(19) United States
(12) Patent Application Publication
(10) Pub. No.: US 2026/0040964 A1
(43) Pub. Date: Feb. 5, 2026

(54) SEMICONDUCTOR PACKAGE INCLUDING A MOLDED INTERCONNECT

(71) Applicant: Texas Instruments Incorporated, Dallas, TX (US)

(72) Inventors: Makoto Shibuya, Setagaya-ku (JP); Woochan Kim, San Jose, CA (US); Kwang-Soo Kim, Sunnyvale, CA (US)

(21) Appl. No.: 18/791,067

(22) Filed: Jul. 31, 2024

(51) Int. Cl. H01L 23/498; H01L 21/48; H01L 23/00; H01L 23/31; H01L 23/367; H01L 23/495; H01L 25/00; H01L 25/065; H01L 29/20

(52) U.S. Cl. CPC H01L 23/49861; H01L 21/4825; H01L 23/49575; H01L 24/13; H01L 25/0657; H01L 25/50; H01L 23/3107; H01L 23/367; H01L 24/16; H01L 24/32; H01L 24/73; H01L 2224/13139; H01L 2224/16245; H01L 2224/32245; H01L 2224/73253; H01L 2225/06572; H10D 62/8503

(57) ABSTRACT

A semiconductor package contains a first semiconductor die, electrically coupled to a plurality of leads around a perimeter of the semiconductor package via a molded interconnect. The molded interconnect comprises a plurality of embedded interconnects in a first mold compound which electrically couple the plurality of bond pads of the first semiconductor die to the plurality of leads of the semiconductor package. The molded interconnect may have a greater cross-sectional area at a given pitch compared to a similar wire bonded semiconductor package and allow advantageous thermal management of the semiconductor package compared to other electrical coupling techniques. The molded interconnect may allow small high-power integrated circuits to be packaged with a package footprint which is smaller than would otherwise be available.

### TECHNICAL FIELD

This disclosure relates to the field of semiconductor packages. More particularly, but not exclusively, this disclosure relates to semiconductor packages including a molded interconnect.

### BACKGROUND

Semiconductor packages are being continually improved to reliably operate and dissipate heat from higher power integrated circuits with smaller footprints. Fabricating semiconductor packages that meet the heat dissipation, reliability requirements, and footprint requirements presents diverse challenges.

### SUMMARY

A semiconductor package contains a first semiconductor die, herein referred to as the first die, electrically coupled to a plurality of leads around a perimeter of the semiconductor package via a molded interconnect. The molded interconnect comprises a plurality of embedded interconnects which are embedded in a first mold compound and which electrically couple a plurality of bond pads of the first die to the plurality of leads of the semiconductor package. After the first die is coupled to the plurality of leads through the embedded interconnects of the molded interconnect, a second mold compound is formed over the molded interconnect, the plurality of leads, and the first die.

A multi-integrated circuit semiconductor package may also be formed with a molded interconnect. In the case of a multi-integrated circuit semiconductor package, a first die is electrically coupled to the plurality of leads through a molded interconnect. After the first die is electrically coupled, vias may be formed from the top surface of the molded interconnect to expose a portion of the embedded interconnects of the molded interconnect. An interconnect system may be formed, and a second die electrically coupled through the interconnect system to the embedded interconnects of the molded interconnect. In this way, more than one die may be electrically coupled to a plurality of leads through a molded interconnect.

A multi-chip package may have a gallium nitride (GaN) die as a first die. The first die may be coupled to the die pad of a lead frame of the semiconductor package. A molded interconnect comprising an embedded interconnect in a first mold compound may electrically couple the bond pad of the first die to a lead of the lead frame. A second die on the molded interconnect may be electrically coupled to the embedded interconnect of the molded interconnect, and a second mold compound may cover the leads of the lead frame, the first die, the molded interconnect and the second die.

### BRIEF DESCRIPTION OF THE FIGURES

FIG. 1A is a top-down view of an example semiconductor package with a semiconductor component on a semiconductor package lead frame.

FIG. 1B-1G are cross sectional views of an example semiconductor package in various states of formation.

FIG. 1H is a perspective view of an example semiconductor package after formation.

FIG. 2A-2C are cross sections of an example semiconductor package in various states of formation.

FIG. 2D is a perspective view of an example semiconductor package after formation.

FIG. 3A-3H are perspective views of an example semiconductor package in various states of formation.

### DETAILED DESCRIPTION

The present disclosure is described with reference to the attached figures. The figures are not drawn to scale and they are provided merely to illustrate the disclosure. Several aspects of the disclosure are described below with reference to example applications for illustration. It should be understood that numerous specific details, relationships, and methods are set forth to provide an understanding of the disclosure. The present disclosure is not limited by the illustrated ordering of acts or events, as some acts may occur in different orders and/or concurrently with other acts or events. Furthermore, not all illustrated acts or events are required to implement a methodology in accordance with the present disclosure.

In addition, although some of the examples illustrated herein are shown in two dimensional views with various regions having depth and width, it should be clearly understood that these regions are illustrations of only a portion of a device that is actually a three-dimensional structure. Accordingly, these regions will have three dimensions, including length, width, and depth, when fabricated on an actual device. Moreover, while the present disclosure may be illustrated by examples directed to active devices, it is not intended that these illustrations be a limitation on the scope or applicability of the present disclosure. It is not intended that the active devices of the present disclosure be limited to the physical structures illustrated. These structures are included to demonstrate the utility and application of the present disclosure to various examples.

It is noted that terms such as top, bottom, over, above, and under may be used in this disclosure. These terms should not be construed as limiting the position or orientation of a structure or element, but should be used to provide spatial relationship between structures or elements. The terms “lateral” and “laterally” refer to directions parallel to a plane corresponding to a surface of a layer, for example a top surface of a semiconductor substrate. Moreover, unless otherwise specified, the term “approximately,” as used herein, may refer to ±5% to ±10% variations of the recited values in some cases. In other cases, the term “approximately” may refer to ±10% to ±20% variations of the recited values.

A semiconductor package contains a first semiconductor die, herein referred to as the first die, electrically coupled to a plurality of leads around a perimeter of the semiconductor package via a molded interconnect. The molded interconnect comprises a plurality of embedded interconnects which are embedded in a first mold compound which electrically couples a plurality of bond pads of the first die to the plurality of leads of the semiconductor package. It may be advantageous to couple a first die to the plurality of leads through a molded interconnect, as the embedded interconnects of the molded interconnect may have a greater cross-sectional area at a given pitch compared to a bond wire coupled to the leads of the lead frame. A greater cross-sectional area of the connection between the first die and the plurality of leads of the lead frame is advantageous for thermal management of the semiconductor package. By using a molded interconnect, small high-power integrated circuits may be packaged with a package footprint which is smaller than would otherwise be available if the integrated circuit were directly connected to the plurality of leads through wire bonds or other similar electrical coupling techniques. After the first die is coupled to the plurality of leads through the embedded interconnects of the molded interconnect, a second mold compound is formed over the molded interconnect, the plurality of leads, and the first die.

A multi-integrated circuit semiconductor package may also be formed with a molded interconnect. In the case of a multi-integrated circuit semiconductor package, a first die which may be a gallium nitride (GaN) die is electrically coupled to the plurality of leads through a molded interconnect. After the first die is electrically coupled, vias may be formed from the top surface of the molded interconnect to expose a portion of the embedded interconnects of the molded interconnect. An interconnect system may be formed, and a second die electrically coupled through the interconnect system to the embedded interconnects of the molded interconnect. In this way, more than one die may be electrically coupled to a plurality of leads through a molded interconnect.

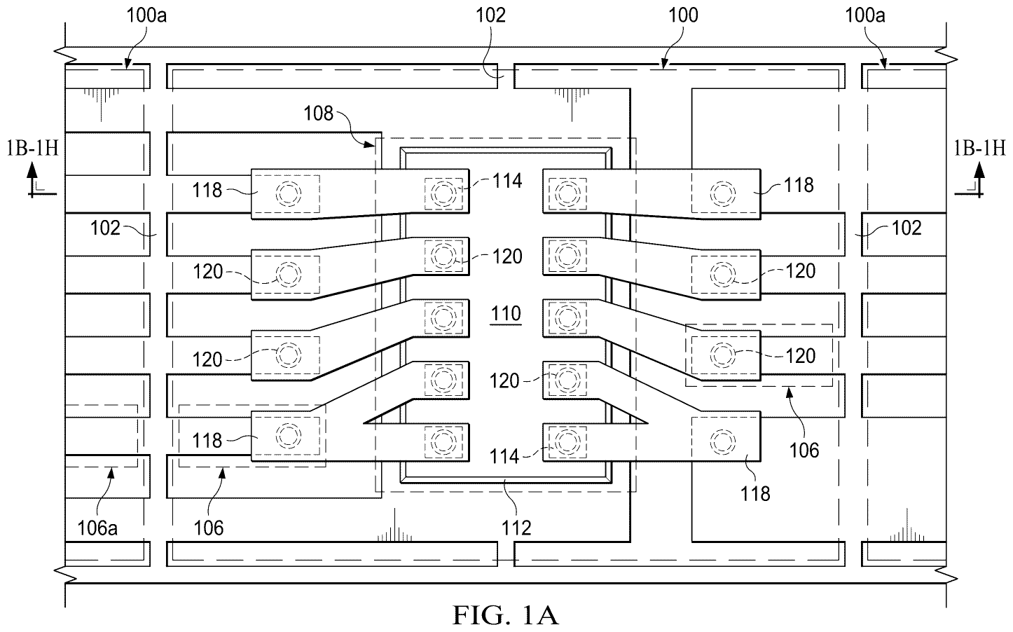

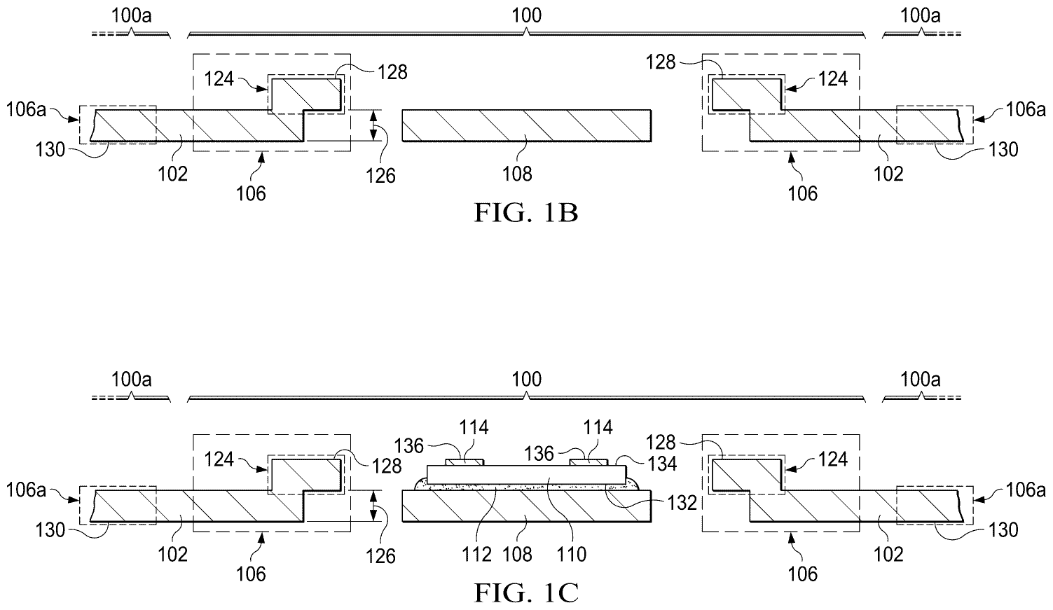

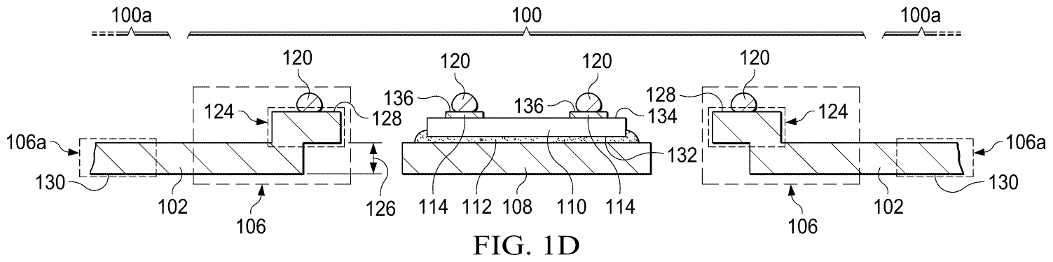

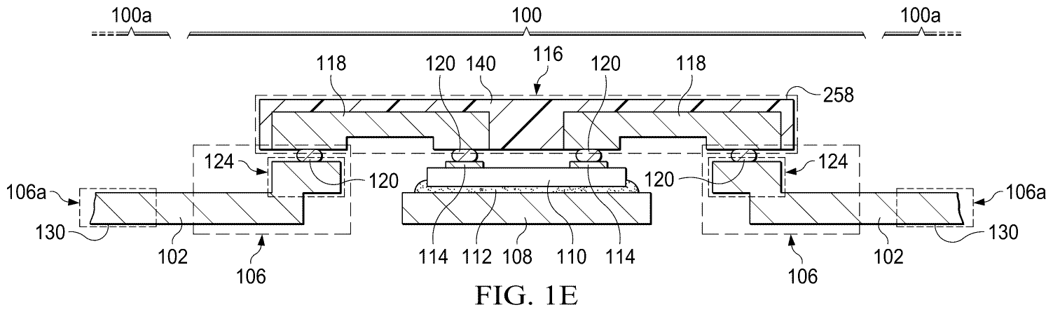

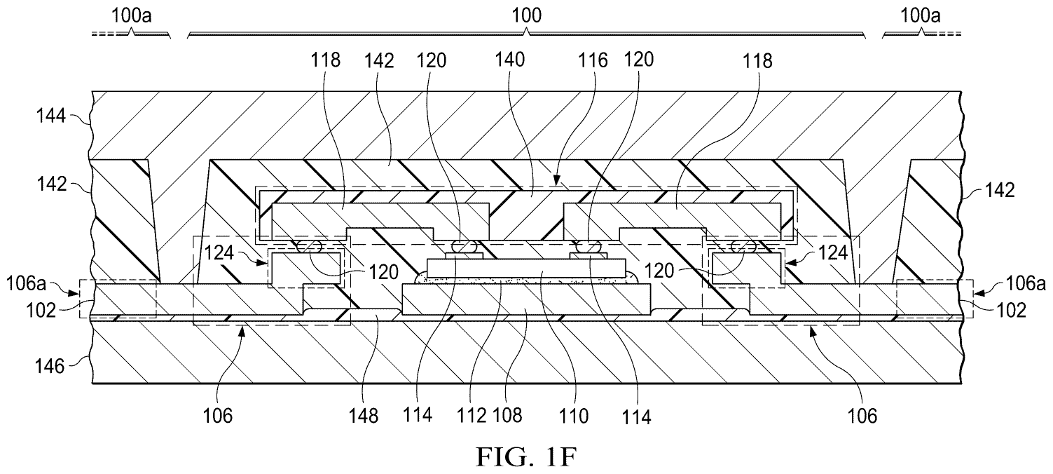

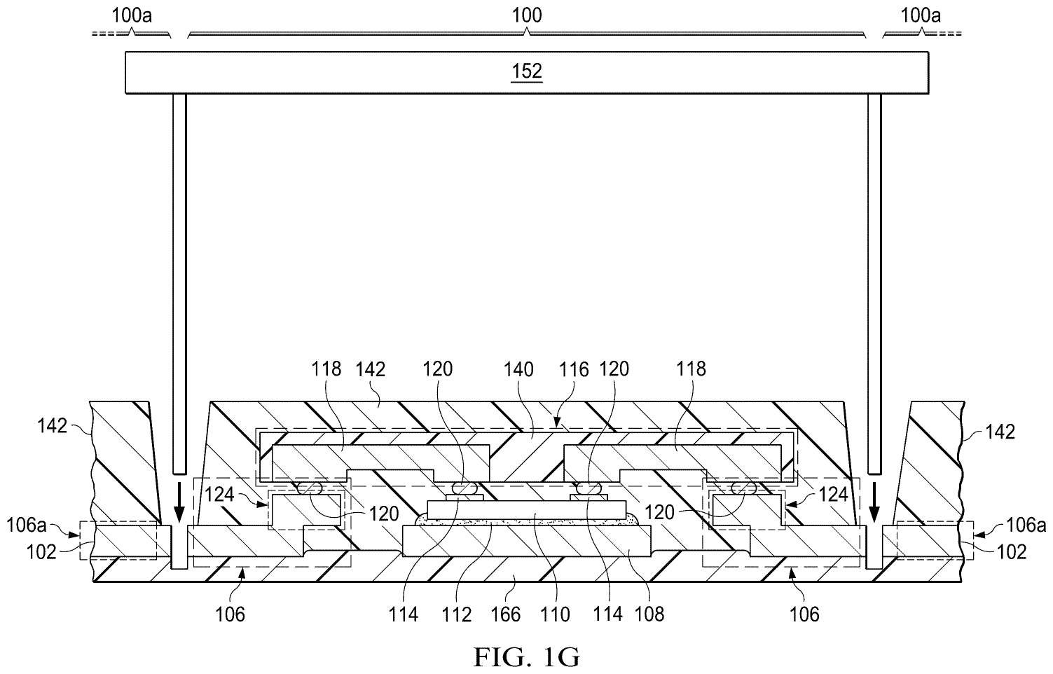

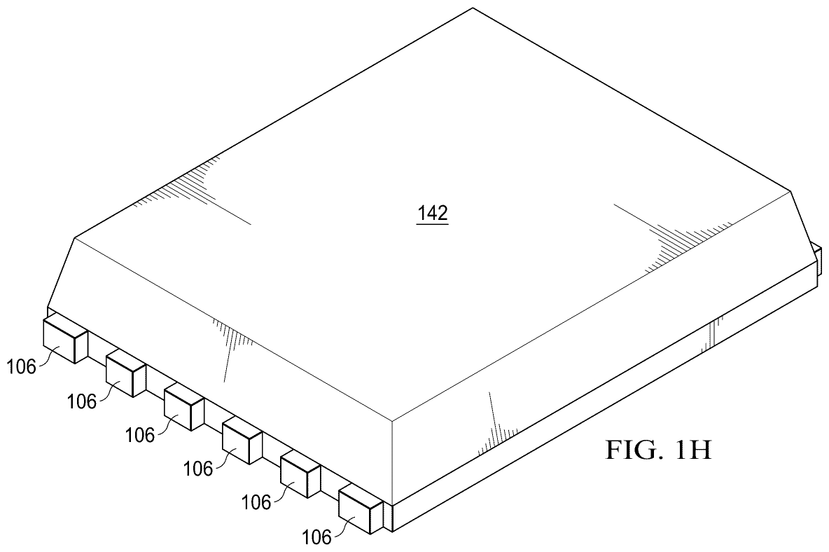

FIG. 1A is a top-down view of the semiconductor package 100 before a second mold compound 142 (referred to in FIG. 1F) is formed. Referring to FIG. 1A, the semiconductor package 100 may be formed on a lead frame 102. The lead frame 102 of the example semiconductor package referred to in FIG. 1A-FIG. 1H is a rolled lead frame which accommodates an adjacent semiconductor packages 100a on each side of the semiconductor package 100.

The semiconductor package 100 includes a lead 106, herein referred to as a plurality of leads 106, the plurality of leads 106 being part of a lead frame 102. Similarly, the adjacent semiconductor package 100a also includes a plurality of leads 106a. The semiconductor package 100 of this example includes a die pad 108 connected to the lead frame 102.

A first semiconductor die 110 herein referred to as the first die 110 is attached to the die pad 108. The first die 110 may be manifested as an integrated circuit, a discrete component such as a power transistor, a passive component such as a transformer or a filter, a micro electromechanical system (MEMS) component, a sensor, an actuator, a microfluidic component, or an electro-optical component such as a micro-mirror array component, by way of example. The first die 110 may be formed from a substrate of silicon, silicon carbide, gallium nitride (GaN), or gallium arsenide, by way of example. A back side 132 (referred to in FIG. 1C) of the first die 110 may be attached to the die pad 108 by a die attach material 112, such as solder, an electrically conductive adhesive, an electrically insulating adhesive, or a eutectic metal alloy. When the first die 110 is bonded to the die pad 108, bond pad 114 herein referred to as a plurality of bond pads 114 of a top surface 134 (referred to in FIG. 1C) of the first die 110 are exposed.

A molded interconnect 116 (referred to in FIG. 1E) is on the first die 110 and contains a plurality of electrically separate embedded interconnects 118 herein referred to as the plurality of embedded interconnects 118 or an embedded interconnect 118. The plurality of embedded interconnects 118 of the molded interconnect 116 are shown in FIG. 1A while a first mold compound 140 of the molded interconnect 116 is not shown in FIG. 1A for clarity. The plurality of embedded interconnects 118 is conductively coupled to the plurality of bond pads 114 of the first die 110 and the plurality of leads 106 of the lead frame 102 by an interconnect conductive material 120. The pitch of the plurality of embedded interconnects 118 may vary from the distal to proximal end of the embedded interconnect 118 allowing the plurality of embedded interconnects 118 to bond the plurality of bond pads 114 which may be tightly spaced on the first die 110 at the proximal end of the plurality of embedded interconnects 118 and bond to plurality of leads 106 of the lead frame 102 at a different pitch at the distal end of the plurality of embedded interconnects 118.

FIG. 1B through FIG. 1G are example cross sections during the formation of the semiconductor package 100. FIG. 1B, is a cross section of the lead frame 102 of the semiconductor package 100 through the plane shown in FIG. 1A. The lead frame 102 is connected to the plurality of leads 106 of the semiconductor package 100 and the plurality of leads 106a of the adjacent semiconductor package 100a. The die pad 108 is between the plurality of leads 106. The die pad 108 is connected to the lead frame 102 as shown in FIG. 1A, however, the connections of the die pad 108 to the lead frame 102 are out of the plane of the cross sections of FIG. 1B-FIG. 1G. A lead frame connection region 124 may be cantilevered as shown in FIG. 1B above the bottom surface 130 of the lead frame 102 by a cantilever height 126 as indicated in FIG. 1B,

Referring to FIG. 1C, a cross section of the semiconductor package 100 is shown after the first die 110 is bonded to the die pad 108 with a die attach material 112. The first die 110 is bonded to the die pad 108 through the back side 132 of the first die 110. The top surface 134 of the first die 110 contains the plurality of bond pads 114 of the first die 110. A top surface 136 of the plurality of bond pads 114 may be above the top surface 134 of the first die 110 as shown in FIG. 1C, or may be approximately equivalent in height (not specifically shown) with the top surface 136 of the first die 110. The cantilever height 126 is such that the top surface 128 of the lead frame connection region 124 is coplanar or is approximately at the same height above the top surface 128 of the lead frame connection region 124 to the top surface 136 of the plurality of bond pads 114. For the purpose of the disclosure, “approximately at the same height” is defined as the difference in height between the top surface 136 of the plurality of bond pads 114 compared to the top surface 128 of the lead frame connection region 124 being less than five percent of the average thickness of the plurality of leads 106, the height of each being measured from the bottom surface 130 of the lead frame. It may be advantageous for the top surface 128 of the lead frame connection region 124 and the top surface 136 of the plurality of bond pads 114 of the first die 110 to be approximately at the same height to facilitate the conductive coupling of the plurality of leads 106 to the plurality of bond pads 114 of the first die 110 through the molded interconnect 116 (referred to in FIG. 1E)

Referring to FIG. 1D, a cross section is shown after the interconnect conductive material 120 is formed on the top surface 136 of the plurality of bond pads 114 of the first die 110 and the top surface 128 of the lead frame connection region 124. The interconnect conductive material 120 may be any conductive material used for die attach like processes (such as solder ball bonds, sinter materials for a reflow like sinter, or other similar materials).

Referring to FIG. 1E, a cross section is shown of the semiconductor package 100 after a molded interconnect 116 is attached to the semiconductor package 100. The molded interconnect 116 consists of a plurality of embedded interconnects 118 within a first mold compound 140. The molded interconnect 116 provides a conductive pathway between the plurality of bond pads 114 of the first die 110 and the plurality of leads 106 of the lead frame 102 through the plurality of embedded interconnects 118 of the molded interconnect 116. It may be advantageous to couple a first die 110 to the plurality of leads 106 through a molded interconnect 116 as the plurality of embedded interconnects 118 of the molded interconnect 116 may have a pitch less than the pitch of the plurality of leads 106 of the lead frame 102 and may have a cross-sectional area equal to or greater than that of a comparable wire bond conductively coupled to plurality of leads 106 the lead frame 102. A greater cross-sectional area of the plurality of embedded interconnects 118 electrically coupling the first die 110 and the plurality of leads 106 of the lead frame 102 compared to a wire bond may be advantageous for thermal management and reducing the overall footprint of the semiconductor package 100. By using a molded interconnect 116, with a tight pitch which allows a large cross sectional area embedded interconnects 118 to be coupled to the tight pitch bond pads of small high-power integrated circuits may meet the demanding thermal package requirements for the semiconductor package 100 with a package footprint which is smaller than would otherwise be available if the first die 110 were directly connected to the plurality of leads 106 through multiple wire bonds or other similar electrical coupling techniques (not specifically shown).

The plurality of embedded interconnects 118 of the molded interconnect 116 are conductively bonded to the plurality of bond pads 114 of the first die 110 and conductively bonded to the plurality of leads 106 through the interconnect conductive material 120.

Referring to FIG. 1F, a cross section is shown of the semiconductor package 100 during the formation of a second mold compound 142. To form the second mold compound 142, the semiconductor package 100 is placed between a top mold compound die 144 and a bottom mold compound die 146. In this example, a compressible mold relief film 148 is located between the bottom mold compound die 146 and the bottom surface 130 of the lead frame 102. The compressible mold relief film 148 compresses between the bottom mold compound die 146 and the lead frame 102 to facilitate the release of the semiconductor package 100 after the second mold compound 142 is formed. The second mold compound 142 is injected between the top mold compound die 144 and the bottom mold compound die 146, covering a portion of or encapsulating the first die 110, the plurality of leads 106, the die pad 108, the interconnect conductive material 120, the die attach material 112, and the molded interconnect 116 of the semiconductor package 100.

Referring to FIG. 1G, a cross section of the semiconductor package 100 is shown during a package shearing/singulation process. A package shearing tool 152 cuts though any second mold compound 142 and through the plurality of leads 106 around the perimeter of the semiconductor package 100 and isolates the semiconductor package 100 from the adjacent semiconductor package 100a. While a shearing process is shown in FIG. 1G, a sawing process is within the scope of the disclosure. The lead frame 102 may Bon a lead frame tape 166 during the shearing process.

FIG. 1H is a perspective view of the semiconductor package 100 including the second mold compound 142 and the plurality of leads 106 after the singulation process referred to in FIG. 1G.

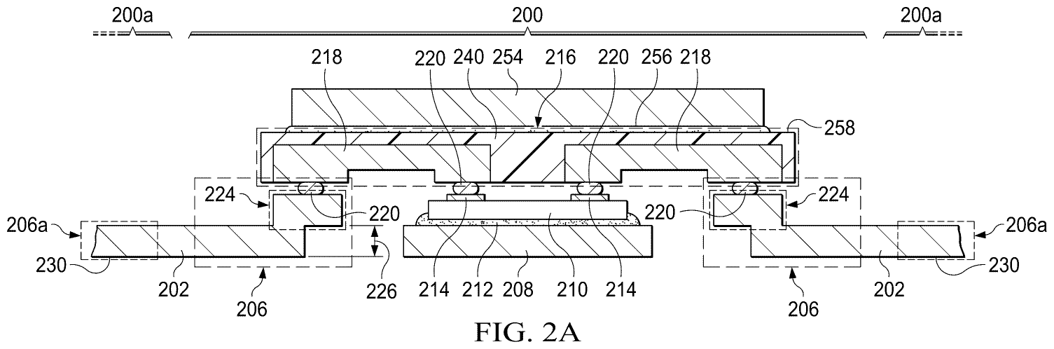

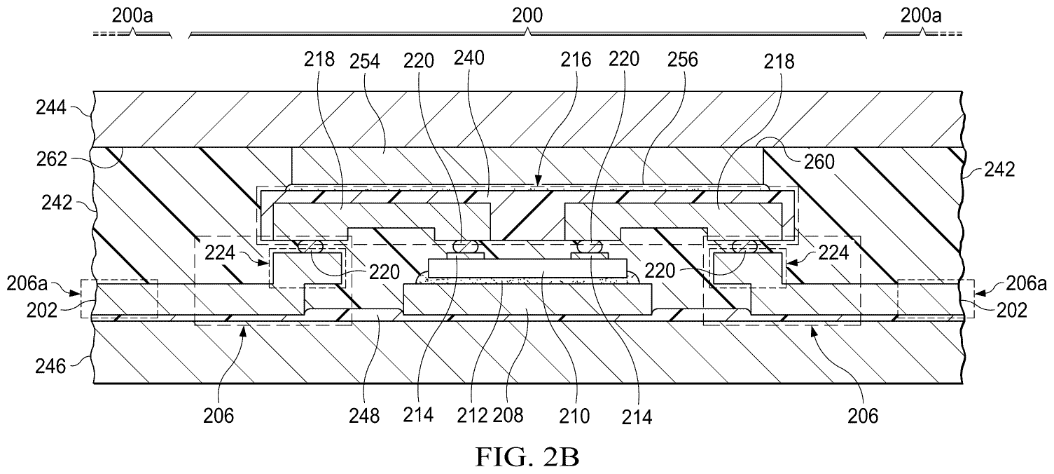

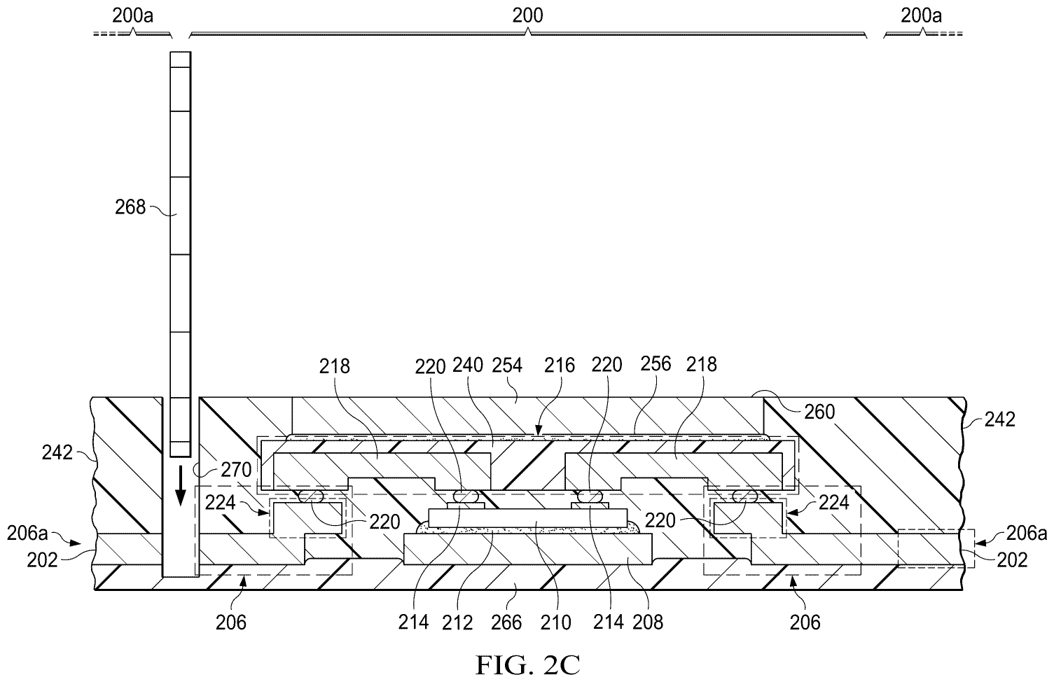

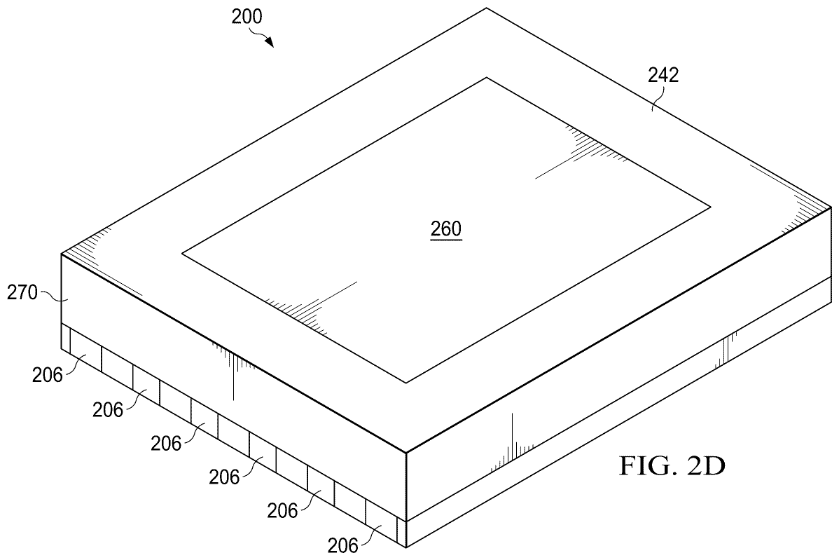

FIG. 2A is a cross-section view of a semiconductor package 200 formed by a process similar to that referred to in FIG. 1A-FIG. 1H, in which the semiconductor package 200 incorporates a heat sink 254 into the semiconductor package 200. Additionally, in a formation process shown in FIG. 2A-FIG. 2D a semiconductor package 200 and additional semiconductor packages 200a in a lead frame 202 are in a two-dimensional array (such as used in a quad flat pack type of packaging formation process) instead of the packaging process referred to in FIG. 1A-FIG. 1H in which the semiconductor package 100 and the adjacent semiconductor packages 100a are on a packaging reel.

After following a formation process similar to FIG. 1A-1E, using a lead frame 202 which is two dimensional in nature, in FIG. 2A, a heat sink 254 is bonded with a heat sink attach compound 256 onto the top surface 258 of the molded interconnect 216. Additional components shown in FIG. 2A include a die pad 208, a plurality of leads 206, the plurality of leads 206 being part of a lead frame 202, a plurality of adjacent leads 206a, a first semiconductor die 210, die attach material 212, a plurality of bond pads 214, an embedded interconnect conductive material 220, a lead frame connection region 224, a first mold compound 240, and a plurality of embedded interconnects 218. The lead frame connection region 224 may be cantilevered as shown in FIG. 2A above the bottom surface 230 of the lead frame 202 by a cantilever height 226.

Referring to FIG. 2B, a cross section is shown of the semiconductor package 200 during the formation of a second mold compound 242. To form the second mold compound 242, the semiconductor package 200 is placed between a top mold compound die 244 and a bottom mold compound die 246, and the second mold compound 242 is injected and covering a portion of and encapsulating the first semiconductor die 210, the plurality of leads 206, the heat sink 254, the embedded interconnect conductive material 220, and the molded interconnect 216 of the semiconductor package 200. A mold compound tape 248 may be placed between the lead frame 202 and the bottom mold compound die 246 to facilitate the release of the semiconductor package 200 after the second mold compound 242 is formed. The top surface 260 of the heat sink 254 is coincident with the bottom surface 262 of the top mold compound die 244 which results in a top surface 260 of the heat sink 254 which may be free of the second mold compound 242.

FIG. 2C is a cross section of the semiconductor package 200 of FIG. 2B at a subsequent stage of formation during a singulation sawing process. Referring to FIG. 2C, the semiconductor package 200 and the additional semiconductor packages 200a are mounted onto a saw tape ring 266, which may also be referred to as a saw film. The semiconductor package 200 is singulated from the additional semiconductor packages 200a by a singulation sawing process using a singulation saw blade 268.

The singulation sawing process cuts through and separates the plurality of leads 206 of the semiconductor package 200 and the plurality of adjacent leads 206a of the additional semiconductor packages 200a, as well as separating the second mold compound 242 between the semiconductor package 200 and the additional semiconductor packages 200a.

FIG. 2D is a perspective view of the semiconductor package 200 after singulation. Features visible on the semiconductor package 200 after singulation include the plurality of leads 206 exposed side faces 270 of the second mold compound 242, and the top surface 260 of the heat sink 254.

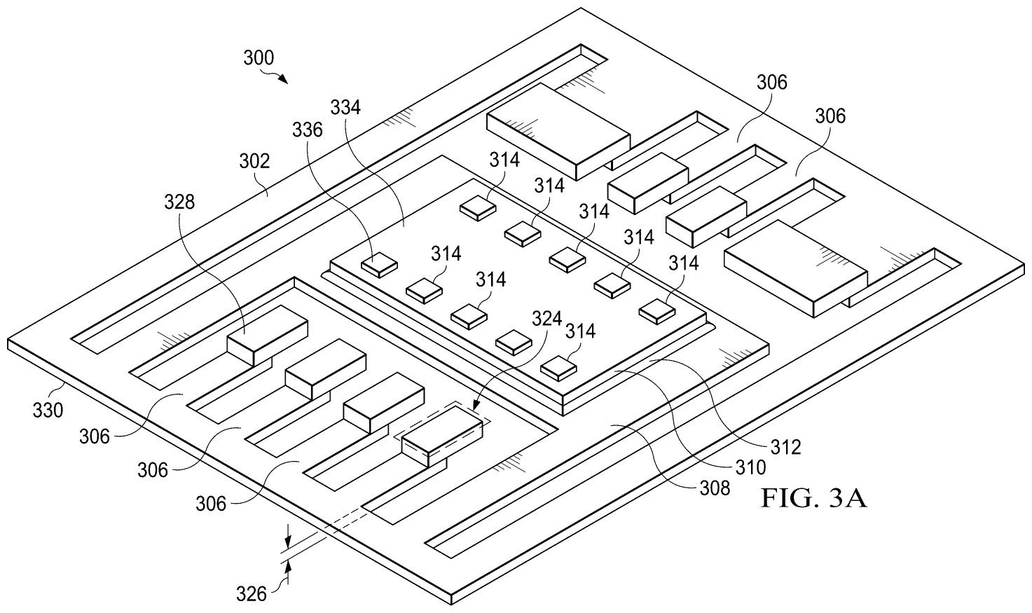

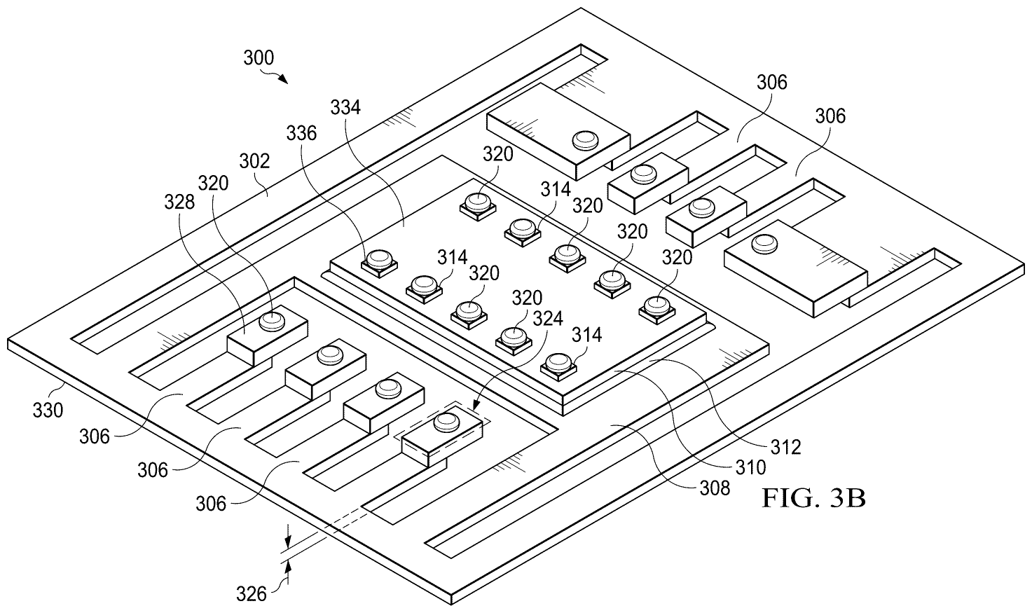

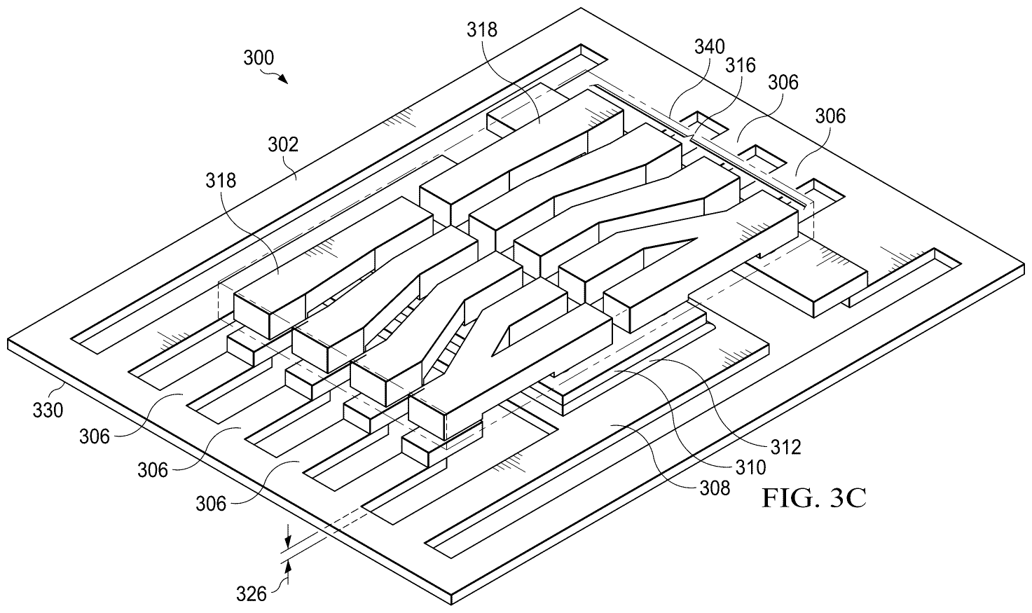

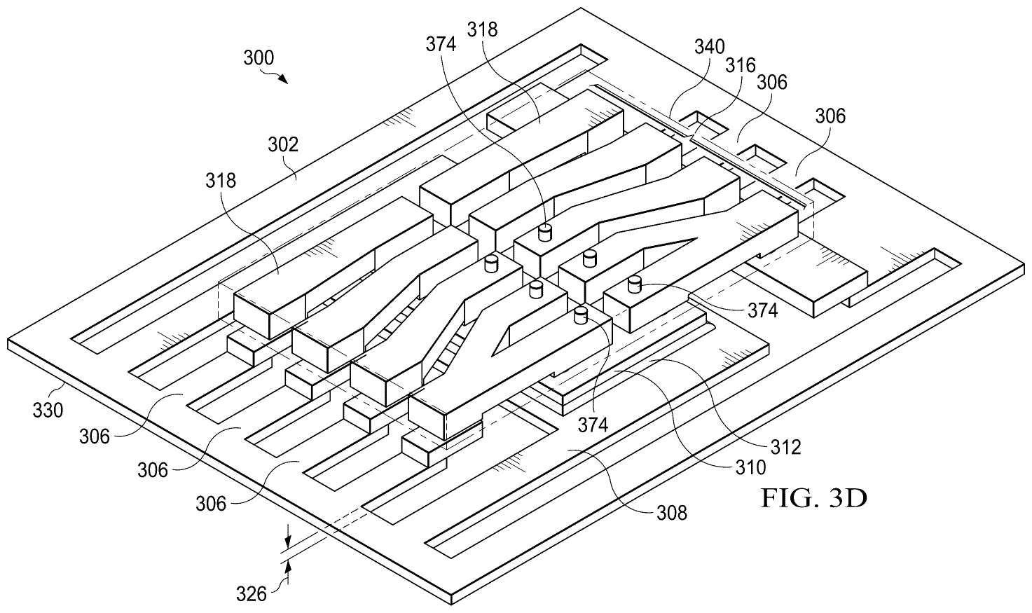

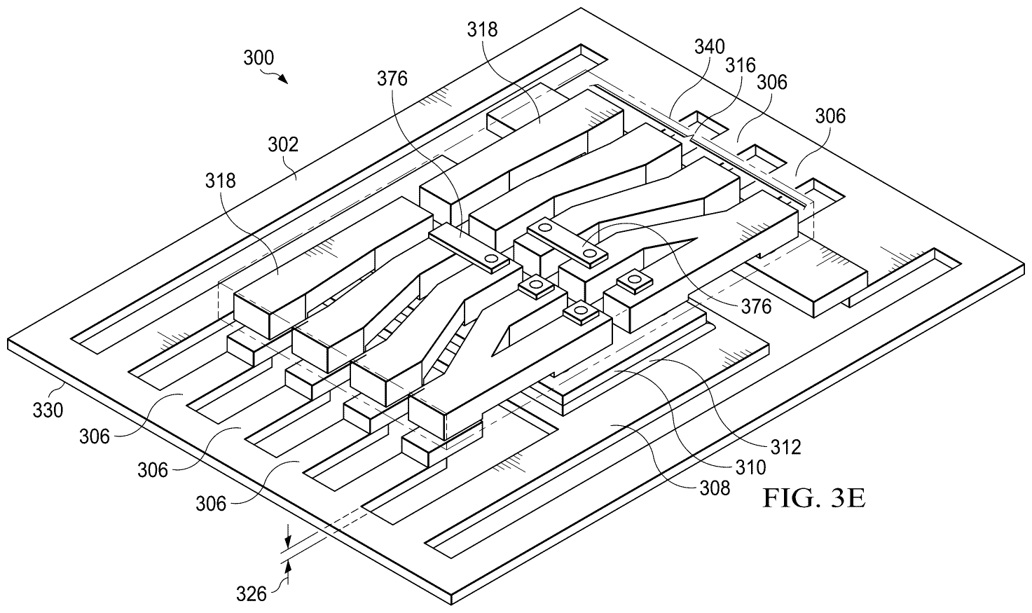

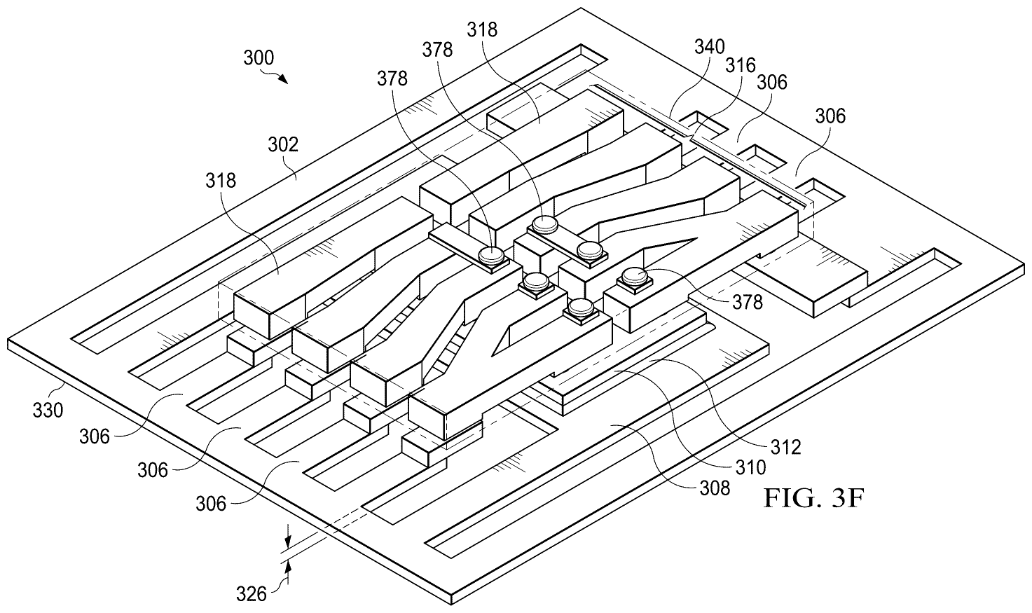

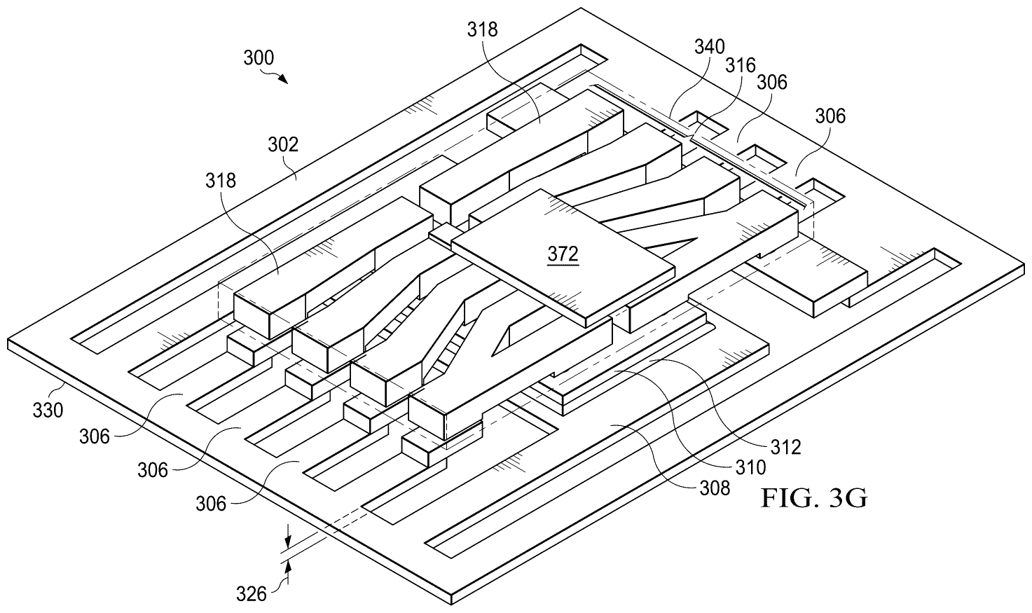

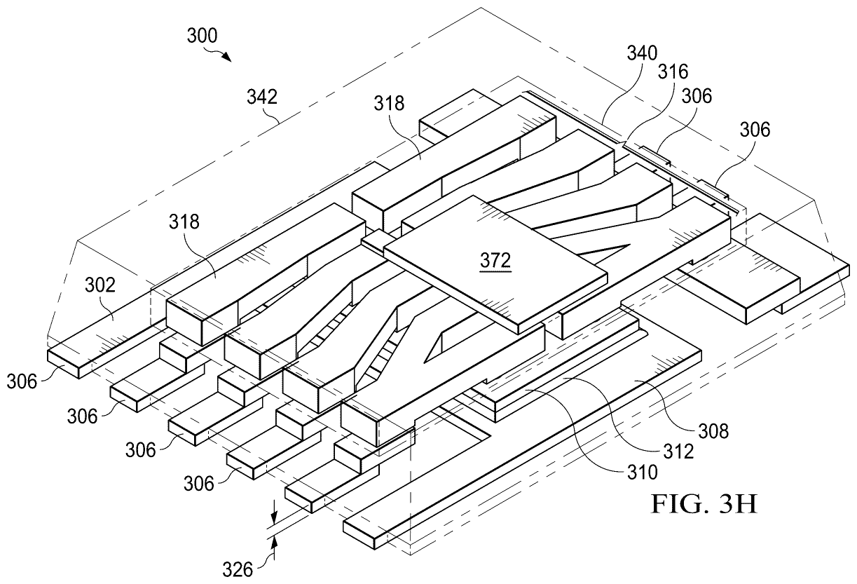

FIG. 3A through FIG. 3H show a formation process of a semiconductor package 300 including a first semiconductor die 310 herein referred to as a first die 310 and a second semiconductor die 372, herein referred to as the second die 372, in which both are electrically connected through the plurality of embedded interconnects 318 of a molded interconnect 316 to the plurality of leads 306 of a lead frame 302. The first die 310 and the second die 372 need not be comprised of the same material, for example, the first die 310 could be comprised of gallium nitride and the second die 372 could be comprised of silicon, any other suitable material can be used for both the first die 310 and the second die 372. Adjacent semiconductor packages of the lead frame 302 are not included in FIG. 3A-FIG. 3H for clarity.

FIG. 3A through FIG. 3C are perspective views of a portion of a semiconductor package formation process similar to the portion of a semiconductor package formation described referring to FIG. 1A-FIG. 1E. FIG. 3D-FIG. 3H refer to additional formation steps including formation of the second die 372 in the semiconductor package 300.

Referring to FIG. 3A, a perspective view is shown of a semiconductor package 300 containing a plurality of leads 306, the plurality of leads being part of the lead frame 302 and after a first die 310 has been attached to a die pad 308 using a die attach material 312. The die pad 308 is surrounded on two sides in the example semiconductor package 300 by the plurality of leads 306. A lead frame connection region 324 may be cantilevered as shown in FIG. 3A above the bottom surface 330 of the lead frame 302 by a cantilever height 326.

The first die 310 is bonded to the die pad 308 such that the top surface 334 of the first die 310 contains the plurality of bond pads 314 of the first die 310. The top surface 336 of the plurality of bond pads 314 may be above the top surface 334 of the first die 310 as shown in FIG. 3A, or may be approximately equal in height (not specifically shown) to the top surface 334 of the first die 310. The cantilever height 326 is such that the top surface 328 of the lead frame connection region 324 is approximately the same height above the bottom surface 330 of the lead frame 302 as the top surface 336 of the plurality of bond pads 314. The approximately equivalent height of the top surface 336 of the plurality of bond pads 314 and the top surface 328 of the lead frame connection region 324 allows the molded interconnect 316 referred to in FIG. 3C to be conductively bonded to the plurality of bond pads 314 and the lead frame connection region 324.

Referring to FIG. 3B, a perspective view is shown after an interconnect conductive material 320 is formed on the top surface 336 of the plurality of bond pads 314 of the first die 310 and on the top surface 328 of the lead frame connection region 324. The interconnect conductive material 320 may be any conductive material used for die attach like processes (such as solder ball bonds, sinter materials for a reflow like sinter, or other similar materials). Alternatively, the interconnect conductive material 320 may be first formed on the molded interconnect 316 to allow electrical coupling of the molded interconnect 316 to the lead frame connection region 324 and the plurality of bond pads 314 (not specifically shown).

Referring to FIG. 3C, a perspective view is shown of the semiconductor package 300 after a molded interconnect 316 is bonded to the plurality of bond pads 314 and the lead frame connection region 324 of the plurality of leads 306 through the interconnect conductive material 320. The molded interconnect 316 consists of a plurality of embedded interconnects 318 within a first mold compound 340. The molded interconnect 316 provides a conductive pathway between the plurality of bond pads 314 of the first die 310 and the plurality of leads 306 of the lead frame 302 through the plurality of embedded interconnects 318 of the molded interconnect 316.

It may be advantageous to couple the first die 310 and the second die 372 (referred to in FIG. 3G) to the plurality of leads 306 through a molded interconnect 316 as the plurality of embedded interconnects 318 of the molded interconnect 316 may have a pitch less than the pitch of the plurality of leads 306 of the lead frame 302 and may have a cross-sectional area equal to or greater than that of the plurality of leads 306 of the lead frame 302. The more aggressive pitch for a given cross-sectional area of the plurality of embedded interconnects 318 may be advantageous as a greater cross-sectional arca may allow more efficient heat dissipation from the first die 310 and the second die 372 than if wire bonds were used. Additional it may allow a smaller overall footprint of the semiconductor package 300, especially when the first die 310 is a higher power semiconductor device with aggressive bond pad spacing and where heat dissipation requirements are demanding as multiple wire bonds to each bond pad may be required for thermal management.

Referring to FIG. 3D, a perspective view is shown after a plurality of first die to second die vias 374 is formed in the first mold compound 340. The plurality of first die to second die vias 374 consists of holes in the first mold compound 340 that extend from the top surface of the first mold compound 340 and contact the plurality of embedded interconnects 318 of the molded interconnect 316. The plurality of first die to second die vias 374 may be formed using a laser in a through mold via process or any similar process for forming vias in a mold compound. The plurality of first die to second die vias 374 may be filled with a conductive material at this point in the formation process, or may be filled with a conductive material during the formation of a plurality of first die to second die interconnects 376 referred to in FIG. 3E.

Referring to FIG. 3E, a perspective view is shown after the plurality of first die to second die interconnects 376 is formed contacting the plurality of first die to second die vias 374. The plurality of first die to second die interconnects 376 may be formed in a manner similar to the plurality of first die to second die vias 374, with the plurality of first die to second die interconnects 376 being formed as a trench in the first mold compound which does not extend down through the first mold compound 340 to the plurality of embedded interconnects 318 of the molded interconnect 316. The plurality of first die to second die vias 374 and the plurality of first die to second die interconnects 376 may be filled with a conductive material using a reflow like sinter using a silver paste or other conductive material deposition processor suitable for mold compounds.

Referring to FIG. 3F, a perspective view is shown after a first die to second die conductive material 378 is formed on the plurality of first die to second die interconnects 376. The formation of the first die to second die conductive material 378 may be a process similar to the formation of the interconnect conductive material 320 and may be any conductive material used for die attach like processes (such as solder ball bonds, sinter materials for a reflow like sinter, or other similar materials. Alternatively, the first die to second die conductive material 378 may be first formed on a second die 372 (referred to in FIG. 3G) to allow bonding the second die 372 to the plurality of first die to second die interconnects 376. (not specifically shown).

Referring to FIG. 3G, a perspective view is shown after a second die 372 is conductively bonded in the semiconductor package 300. The second die 372 is conductively bonded to the plurality of first die to second die interconnects 376 through the first die to second die conductive material 378 via a reflow like sinter using a silver paste or other conductive material or other die attach process.

FIG. 3H is a perspective view after a second mold compound 342 has been formed and the semiconductor package 300, has been singulated from other semiconductor packages of the lead frame 302 (not specifically shown via a shearing singulation process similar to that referred to in FIG. 1G or a sawing process similar to that referred to in FIG. 2C.

While various embodiments of the present disclosure have been described above, it should be understood that they have been presented by way of example only and not limitation. Numerous changes to the disclosed embodiments can be made in accordance with the disclosure herein without departing from the spirit or scope of the disclosure. Thus, the breadth and scope of the present invention should not be limited by any of the above described embodiments. Rather, the scope of the disclosure should be defined in accordance with the following claims and their equivalents.

What is claimed is:

1. A semiconductor package, comprising:
a die pad adjacent to a lead of the semiconductor package;
a first die having a top face and a bottom face, the bottom face of the first die being coupled to the die pad and the top face of the first die having a bond pad;
a molded interconnect having a top face and a bottom face comprising an embedded interconnect in a first mold compound, wherein the embedded interconnect is electrically coupled to the bond pad and the lead; and
a second mold compound covering portions of the lead, the first die, and the molded interconnect.

2. The semiconductor package of claim 1 wherein a top surface of a lead frame connection region of the lead and the top surface of the bond pad of the first die are coplanar, with a difference in height of less than five percent of an average thickness of the lead.

3. The semiconductor package of claim 1 wherein an electrically conductive material electrically couples the embedded interconnect to a bond pad connection region of the bond pad and a lead frame connection region of the lead.

4. The semiconductor package of claim 1 wherein the lead has a cantilever in which a lead frame connection region of the lead is above the top face of the lead.

5. The semiconductor package of claim 1 further including a silver connection as an electrically conductive material electrically coupling the embedded interconnect to a bond pad connection region of the bond pad and a lead frame connection region of the lead.

6. The semiconductor package of claim 1, further including a heat sink contacting the first mold compound of the molded interconnect, a portion of a top face of the heat sink is exposed on a surface of the second mold compound.

7. The semiconductor package of claim 1, wherein a bond pad of a second die is electrically coupled to the embedded interconnect, and in which a portion of the embedded interconnect is electrically coupled to the lead and another portion is electrically coupled to the first die.

8. The semiconductor package of claim 1, wherein a cross-sectional area of the embedded interconnect is equal to or greater than a cross-sectional area of the lead.

9. The semiconductor package of claim 1, wherein a pitch of the embedded interconnect in the molded interconnect varies from a distal to a proximal end of the embedded interconnect.

10. The semiconductor package of claim 1, wherein a cross-sectional area of the embedded interconnect is equal to or greater than a cross-sectional area of the lead.

11. A semiconductor package, comprising:
a die pad adjacent to a lead of the semiconductor package;
a first die having a top face and a bottom face, the bottom face of the first die being coupled to the die pad and the top face of the first die having a bond pad;
a molded interconnect having a top face and a bottom face comprising an embedded interconnect in a first mold compound, wherein the embedded interconnect is electrically coupled to the bond pad of the first die and the lead;
a second die on the top face of the molded interconnect, the second die including a bottom face, the bottom face having a bond pad, wherein the bond pad of the second die is electrically coupled to the embedded interconnect of the molded interconnect through first die to second die interconnects; and
a second mold compound covering portions of the lead, the first die, the molded interconnect and the second die.

12. The semiconductor package of claim 11 wherein the first die includes gallium nitride (GaN).

13. A method of forming a semiconductor package, comprising:
coupling a bottom face of a first die to a die pad of a lead frame, the lead frame comprising the die pad and a lead, a top face of the first die having a bond pad;
electrically coupling the bond pad of the first die to a bond pad connection region of an embedded interconnect of a molded interconnect, the wherein the embedded interconnect is in a first mold compound;
electrically coupling the lead of the lead frame to a lead frame connection region of the embedded interconnect of the molded interconnect; and
forming a second mold compound on the lead frame, the first die and the molded interconnect, the second mold compound having a top surface.

14. The method of claim 13 wherein a top surface of the lead frame connection region of the lead and a top surface of the bond pad of the first die are coplanar and have a difference in height less than five percent of an average thickness of the lead of the lead frame.

15. The method of claim 13 comprising forming with an electrically conductive material, an electrically coupling between the embedded interconnect to the bond pad connection region to the bond pad and to the lead frame connection region to the lead of the lead frame.

16. The method of claim 13 wherein the lead of the lead frame includes a cantilever in which a lead frame connection region of the lead of the lead frame is above the top face of the lead frame.

17. The method of claim 13, wherein electrically coupling the embedded interconnect to a bond pad connection region of the bond pad and a lead frame connection region of the lead of the lead frame includes a reflow like sinter comprised of a silver paste as an electrically conductive material.

18. The method of claim 13, comprising placing a heat sink contacting the first mold compound on the top surface of the first mold compound, a portion of a top face of the heat sink is exposed on a surface of the second mold compound.

19. The method of claim 13, comprising forming an electrical coupling between a second die on the molded interconnect to the embedded interconnect of the molded interconnect.

20. The method of claim 13, comprising forming an electrical coupling of a second die on the molded interconnect in which the bond pad of the second die is electrically coupled to the embedded interconnect and electrically coupled to the first die.
